(19) United States
(12) Patent Application Publication
(10) Pub. No.: US 2026/0322363 A1
(43) Pub. Date: Oct. 15, 2026

(54) ATTENUATOR CIRCUIT

(71) Applicant: Murata Manufacturing Co., Ltd., Nagaokakyo-shi (JP)

(72) Inventors: Chinami SAEGUSA, Nagaokakyo-shi (JP); Yuuta MIYAZAKI, Nagaokakyo-shi (JP); Katsuya SHIMIZU, Nagaokakyo-shi (JP)

(73) Assignee: Murata Manufacturing Co., Ltd., Nagaokakyo-shi (JP)

(21) Appl. No.: 19/466,656

(22) Filed: Feb. 2, 2026

(30) Foreign Application Priority Data
Mar. 24, 2025 (JP) 2025-048600

(51) Int. Cl. H03K 5/02

(52) U.S. Cl. CPC H03K 5/02

(57) ABSTRACT

An attenuator circuit includes multiple attenuators connected in series between an input terminal and an output terminal. The multiple attenuators include an first attenuator having the largest attenuation, an second attenuator having the second largest attenuation and connected between the first attenuator and the output terminal, and a third attenuator having the third largest attenuation and connected between the second attenuator and the output terminal. When the substrate is viewed in plan, the first attenuator is disposed between the input terminal and the second attenuator, the second attenuator is disposed between the first and third attenuators, the third attenuator is disposed between the second attenuator and the output terminal, and the ground terminal is disposed between the input terminal and the first attenuator.

### CROSS-REFERENCE TO RELATED APPLICATION

This application claims priority to Japanese Patent Application No. 2025-048600, filed Mar. 24, 2025, the entire contents of which are incorporated herein by reference.

### BACKGROUND

### 1. Field

The present disclosure relates to an attenuator circuit.

### 2. Description of the Related Art

Japanese Unexamined Patent Application Publication No. 2001-7672 discloses a step attenuator including multiple attenuators.

### SUMMARY

An attenuator circuit according to one aspect of the present disclosure includes: a substrate; an input terminal, an output terminal, and a ground terminal disposed on the substrate; and multiple attenuators disposed on the substrate and connected in series between the input terminal and the output terminal. Each of the multiple attenuators includes at least one resistor connected between a path connecting the input terminal and the output terminal and the ground terminal. The multiple attenuators include: a first attenuator having a largest attenuation among the multiple attenuators; a second attenuator having a second largest attenuation among the multiple attenuators, and connected between the first attenuator and the output terminal; and a third attenuator having a third largest attenuation among the multiple attenuators, and connected between the second attenuator and the output terminal. The first attenuator is disposed between the input terminal and the second attenuator when the substrate is viewed in plan. The second attenuator is disposed between the first attenuator and the third attenuator when the substrate is viewed in plan. The third attenuator is disposed between the second attenuator and the output terminal when the substrate is viewed in plan. The ground terminal is disposed between the input terminal and the first attenuator when the substrate is viewed in plan.

An attenuator circuit according to one aspect of the present disclosure includes: a substrate; an input terminal, an output terminal, and a ground terminal disposed on the substrate; and multiple attenuators disposed on the substrate and connected in series between the input terminal and the output terminal. Each of the multiple attenuators includes at least one resistor connected between a path connecting the input terminal and the output terminal and the ground terminal. The multiple attenuators include: a first attenuator having a largest attenuation among the multiple attenuators; a second attenuator having a second largest attenuation among the multiple attenuators, and connected between the first attenuator and the output terminal; and a third attenuator having a third largest attenuation among the multiple attenuators, and connected between the second attenuator and the output terminal. When the substrate is viewed in plan, a first distance between the first attenuator and the ground terminal is shorter than a second distance between the second attenuator and the ground terminal, and the second distance is shorter than a third distance between the third attenuator and the ground terminal.

### BRIEF DESCRIPTION OF THE DRAWINGS

FIG. 1 is a configuration diagram of a communication device according to an embodiment;

FIG. 2 is a circuit configuration diagram of an attenuator circuit according to the embodiment;

FIG. 3 is a layout diagram of the attenuator circuit according to the embodiment;

FIG. 4 is a graph representing the relationship between the attenuation of each attenuator included in the attenuator circuit according to the embodiment and the ground inductance;

FIG. 5A is a graph representing the frequency characteristics of the attenuator circuit according to the embodiment; and

FIG. 5B is a graph representing the frequency characteristics of an attenuator circuit according to a comparative example.

### DESCRIPTION OF THE EMBODIMENTS

Hereinafter, an embodiment of the present invention will be described in detail with reference to the drawings. Note that the embodiment described below is provided only as an example, whether broadly or specifically defined. The numerical values, shapes, materials, components, arrangement and connection forms of the components, and the like described in the following embodiment are merely examples and are not intended to limit the present invention.

Note that the drawings are schematic diagrams in which certain components have been appropriately emphasized, omitted, or scaled for the purpose of illustrating the present invention. Accordingly, they are not necessarily depicted with strict accuracy and may differ from the actual shapes, positional relationships, and proportions. In the drawings, the same reference numerals are given to substantially identical configurations, and repeated explanations may be omitted or simplified.

In the following drawings, the x-axis and y-axis are axes orthogonal to each other on a plane parallel to the main surface of the substrate. The z-axis is an axis perpendicular to the main surface of the substrate, the positive direction of which indicates the upward direction, and the negative direction of which indicates the downward direction.

In the following description, the term “connected” includes not only cases in which elements are directly connected by a connection terminal and/or a wiring conductor, but also cases in which they are electrically coupled with another circuit element interposed therebetween. The phrase “A is switchably connected to B” means that the connection and disconnection of A and B is switchable, i.e., A is connected to B with a switch interposed therebetween. Note that the phrase “A is connected to B” includes “A is switchably connected to B”.

The phrase “C is connected between A and B” means that one of two ends of C is connected to A and the other end of C is connected to B, i.e., C is connected in series with a path connecting A and B. The phrase “C is connected between a path connecting A and B and ground” means that one of two ends of C is connected to a path connecting A and B and the other end of C is connected to ground, i.e., C is connected in shunt to a path connecting A and B. The term “path connecting A and B” refers to a path composed of a conductor electrically coupling A to B.

The term “passband of a band-pass filter” refers to the portion of a frequency spectrum that is transmitted through the filter, and is defined as the frequency band between two frequencies at which the power insertion loss is 3 dB greater than the minimum value of the power insertion loss. The term “cutoff frequency of a low-pass filter or high-pass filter” is defined as the frequency at which the power insertion loss is 3 dB greater than the minimum value of the power insertion loss.

The term “transmission band” refers to the frequency band used for transmission in a communication device, and the term “reception band” refers to the frequency band used for reception in a communication device. For example, in Frequency Division Duplex (FDD) band, different frequency bands (uplink band and downlink band) are used as the transmission and reception bands. In Time Division Duplex (TDD) band, the same frequency band is used as both the transmission and reception bands.

The phrase “a component is disposed on the substrate” includes both cases where the component is disposed on the main surface of the substrate and where the component is disposed within the substrate. The phrase “a component is disposed on the main surface of the substrate” includes cases where the component is disposed in contact with the main surface of the substrate as well as cases where the component is disposed above the main surface without being in contact with the main surface (e.g., stacked on another component disposed in contact with the main surface). Additionally, the phrase “a component is disposed on the main surface of the substrate” may also include cases where the component is disposed in a recess formed in the main surface. The phrase “a component is disposed within the substrate” includes cases where the component is encapsulated in the substrate, cases where the entire component is disposed between the two main surfaces of the substrate but a portion of the component is not covered by the substrate, and cases where only a part of the component is disposed within the substrate.

The phrase “the substrate is viewed in plan” means viewing an object orthogonally projected onto the xy-plane in the negative z-axis direction. The phrase “A overlaps B when the substrate is viewed in plan” means that the area of A orthogonally projected onto the xy-plane overlaps the area of B orthogonally projected onto the xy-plane.

The phrase “A is disposed between B and C” means that at least one of the multiple line segments connecting any point in B to any point in C passes through A. The phrase “A is disposed closer to C than B” means that the distance between A and C is shorter than the distance between B and C. Conversely, “A is disposed farther from C than B” means that the distance between A and C is longer than the distance between B and C. The “distance between A (B) and C” refers to the length of the shortest line segment among the multiple line segments connecting any point on the surface of A (B) to any point on the surface of C.

Terms indicating relationships between elements, such as “parallel” and “perpendicular”, and terms indicating the shapes of elements, such as “straight line”, as well as numerical ranges, do not only denote strict meanings but also include substantially equivalent ranges, for example, with an error of several percent.

In the above-described conventional techniques, the frequency characteristics may deteriorate due to parasitic inductance.

Accordingly, the present disclosure is directed to providing an attenuator circuit capable of improving the frequency characteristics.

According to an attenuator circuit according to one aspect of the present invention, it is possible to improve the frequency characteristics.

### EMBODIMENT

An embodiment will be described.

### 1. Configuration of Communication Device 5

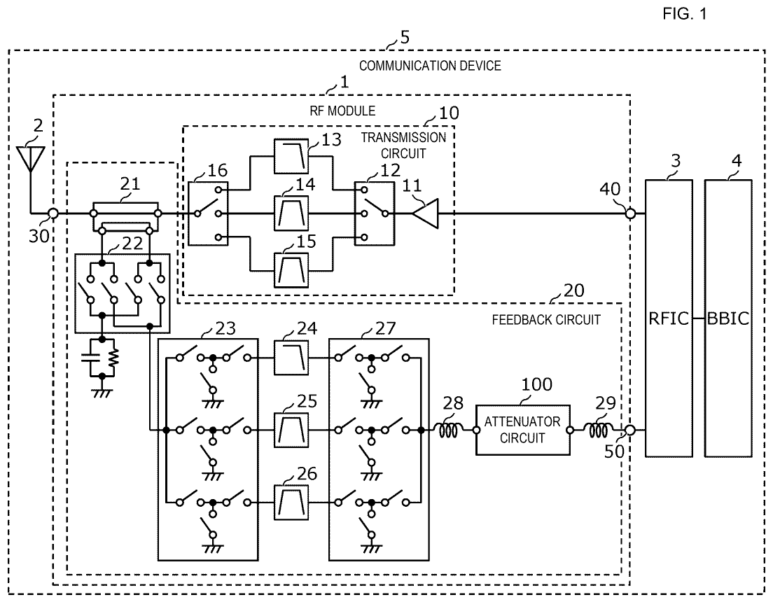

First, a communication device 5 will be described with reference to FIG. 1 as an example of a device to which an attenuator circuit 100 according to the present embodiment is applicable. FIG. 1 is a configuration diagram of the communication device 5 according to the present embodiment.

Note that FIG. 1 is an exemplary configuration diagram, and the communication device 5 may be implemented using any of various circuit implementations and circuit technologies. Accordingly, the following description of the communication device 5 is not to be construed as limiting.

The communication device 5 may be used to provide wireless connectivity. For example, the communication device 5 may be implemented in user equipment (UE) in a cellular network (also referred to as a mobile network) of mobile phones, smartphones, tablet computers, wearable devices, etc. In another example, implementing the communication device 5 may provide wireless connectivity to Internet of Things (IoT) sensor devices, medical/healthcare devices, vehicles, unmanned aerial vehicles (UAVs) (so-called drones), and automated guided vehicles (AGVs). In yet another example, implementing the communication device 5 may also provide wireless connectivity at wireless access points or wireless hotspots.

The communication device 5 includes a radio frequency (RF) module 1, an antenna 2, a radio frequency integrated circuit (RFIC) 3, and a baseband integrated circuit (BBIC) 4.

The RF module 1 is capable of transmitting RF signals between the antenna 2 and the RFIC 3. The circuit configuration of the RF module 1 will be described later. The functionality of the elements disclosed herein (e.g., the RFIC 3) may be implemented using circuitry or processing circuitry which includes general purpose processors, special purpose processors, integrated circuits, ASICs (“Application Specific Integrated Circuits”), FPGAs (“Field Programmable Gate Arrays”), conventional circuitry and/or combinations thereof which are programmed, using one or more programs stored in one or more memories, or otherwise configured to perform the disclosed functionality. Processors are considered processing circuitry or circuitry as they include transistors and other circuitry therein. The processor may be a programmed processor which executes a program stored in a memory. In the disclosure, the circuitry, units, or means are hardware that carry out or are programmed to perform the recited functionality. The hardware may be any hardware disclosed herein which is programmed or configured to carry out the recited functionality.

The antenna 2 is connected to the RF module 1. The antenna 2 is capable of receiving an RF signal from the RF module 1 and transmitting it to the outside of the communication device 5. The antenna 2 may further receive an RF signal from outside the communication device 5 and supply it to the RF module 1. Note that the antenna 2 need not necessarily be included in the communication device 5. The communication device 5 may further include one or more antennas in addition to the antenna 2.

The RFIC 3 is an example of a signal processing circuit that processes RF signals. Specifically, the RFIC 3 is capable of processing a transmission signal input from the BBIC 4 by up-conversion or the like, and outputting the resulting RF transmission signal to the RF module 1. Furthermore, the RFIC 3 may process an RF reception signal input via the RF module 1 by down-conversion or the like, and output the resulting reception signal to the BBIC 4. The RFIC 3 may also include a control unit configured to control switches, amplifiers, and other components included in the RF module 1. Note that some or all of the functions of the RFIC 3 as a control unit may be provided outside the RFIC 3, for example, in the BBIC 4 or in the RF module 1.

The BBIC 4 is a baseband signal processing circuit that performs signal processing using a frequency band lower than that of the RF signals transmitted by the RF module 1. Examples of signals processed by the BBIC 4 include image signals for image display and/or audio signals for voice calls through a speaker. Note that the BBIC 4 need not necessarily be included in the communication device 5.

### 2. Circuit Configuration of RF Module 1

Next, the RF module 1 will be described with reference to FIG. 1 as an example of a front-end module including the attenuator circuit 100 according to the present embodiment. Note that FIG. 1 illustrates an exemplary circuit configuration, and the RF module 1 may be implemented using any of various circuit implementations and circuit technologies. Accordingly, the following description of the RF module 1 is not to be construed as limiting.

The RF module 1 includes a transmission circuit 10, a feedback circuit 20, an antenna connection terminal 30, an RF input terminal 40, and a feedback terminal 50. Note that the RF module 1 may also include a reception circuit.

The antenna connection terminal 30 is an external connection terminal of the RF module 1 and is a terminal for supplying an RF signal to the antenna 2. The antenna connection terminal 30 is connected to the antenna 2 outside the RF module 1, and inside the RF module 1 it is connected to the output end of the transmission circuit 10 with the feedback circuit 20 interposed therebetween.

The RF input terminal 40 is an external connection terminal of the RF module 1 and is a terminal for receiving an RF signal from the RFIC 3. The RF input terminal 40 is connected to the RFIC 3 outside the RF module 1, and inside the RF module 1 it is connected to the input end of the transmission circuit 10.

The feedback terminal 50 is an external connection terminal of the RF module 1 and is a terminal for supplying a feedback signal to the RFIC 3. The feedback terminal 50 is connected to the RFIC 3 outside the RF module 1, and inside the RF module 1 it is connected to the output end of the feedback circuit 20.

The transmission circuit 10 is capable of amplifying transmission signals of multiple bands supplied from the RFIC 3 and supplying the amplified multi-band transmission signals to the antenna 2. The transmission circuit 10 includes a power amplifier 11, switch circuits 12 and 16, and filters 13, 14, and 15.

The power amplifier 11 is connected between the input end of the transmission circuit 10 and the switch circuit 12. Specifically, the input end of the power amplifier 11 is connected to the input end of the transmission circuit 10, and the output end of the power amplifier 11 is connected to the switch circuit 12.

The switch circuit 12 is connected between the output end of the power amplifier 11 and the input ends of the filters 13 to 15. The switch circuit 12 is capable of switching the connection of the power amplifier 11 among the filters 13 to 15.

The filter 13 is a low-pass filter having a cutoff frequency higher than the transmission band of band A. The filter 13 is connected between the switch circuits 12 and 16.

The filter 14 is a band-pass filter having a passband that includes the transmission band of band B. The filter 14 is connected between the switch circuits 12 and 16.

The filter 15 is a band-pass filter having a passband that includes the transmission band of band C. The filter 15 is connected between the switch circuits 12 and 16.

Bands A to C are frequency bands for communication systems constructed using Radio Access Technology (RAT). Bands A to C are predefined by standardization organizations such as 3rd Generation Partnership Project (3GPP; registered trademark) and Institute of Electrical and Electronics Engineers (IEEE). Examples of the communication systems include 5th Generation New Radio (5G NR) systems, 4th Generation Long Term Evolution (4G LTE) systems, and 2nd Generation Global System for Mobile communications (2G GSM) systems.

The switch circuit 16 is connected between the output ends of the filters 13 to 15 and the antenna connection terminal 30. The switch circuit 16 is capable of switching the connection of the antenna connection terminal 30 among the filters 13 to 15.

The feedback circuit 20 is capable of feeding a portion of the transmission signal output from the transmission circuit 10 back to the RFIC 3. The feedback circuit 20 includes a coupler 21, switch circuits 22, 23, and 27, filters 24, 25, and 26, inductors 28 and 29, and the attenuator circuit 100.

The coupler 21 is connected between the transmission circuit 10 and the antenna connection terminal 30. The coupler 21 is a bidirectional coupler with four ports (input port, transmitted port, coupled port, and isolated port). The input port is connected to the output end of the transmission circuit 10. The transmitted port is connected to the antenna connection terminal 30. The coupled port and the isolated port are connected to the switch circuit 22.

The switch circuit 22 is connected between the coupler 21 and the switch circuit 23. The switch circuit 22 is capable of switchably connecting the coupled port and the isolated port of the coupler 21 either to the switch circuit 23 or to a termination. That is, the switch circuit 22 is capable of switching between a first connection state, in which the coupled port is connected to the switch circuit 23 and the isolated port is connected to the termination, and a second connection state, in which the coupled port is connected to the termination and the isolated port is connected to the switch circuit 23.

The switch circuit 23 is connected between the switch circuit 22 and the filters 24 to 26. The switch circuit 23 is capable of switching the connection of the switch circuit 22 among the filters 24 to 26.

The filter 24 is a low-pass filter having a cutoff frequency higher than the transmission band of band A. The filter 24 is connected between the switch circuits 23 and 27.

The filter 25 is a band-pass filter having a passband that includes the transmission band of band B. The filter 25 is connected between the switch circuits 23 and 27.

The filter 26 is a band-pass filter having a passband that includes the transmission band of band C. The filter 26 is connected between the switch circuits 23 and 27.

The switch circuit 27 is connected between the filters 24 to 26 and the output end of the feedback circuit 20. The switch circuit 27 is capable of switching the connection of the output end of the feedback circuit 20 among the filters 24 to 26.

The inductor 28 is connected between the switch circuit 27 and the attenuator circuit 100. The inductor 28 is capable of achieving impedance matching between the switch circuit 27 and the attenuator circuit 100. This makes it possible to improve the frequency characteristics of the attenuator circuit 100. Note that the inductor 28 need not necessarily be included in the feedback circuit 20.

The inductor 29 is connected between the attenuator circuit 100 and the output end of the feedback circuit 20. The inductor 29 is capable of achieving impedance matching between the attenuator circuit 100 and the feedback terminal 50. This makes it possible to improve the frequency characteristics of the attenuator circuit 100. Note that the inductor 29 need not necessarily be included in the feedback circuit 20.

The attenuator circuit 100 is a so-called step attenuator, which is capable of stepwisely adjusting the total attenuation by combining multiple attenuators having different attenuations. The attenuator circuit 100 is connected between the switch circuit 27 and the output end of the feedback circuit 20.

### 3. Circuit Configuration of Attenuator Circuit 100

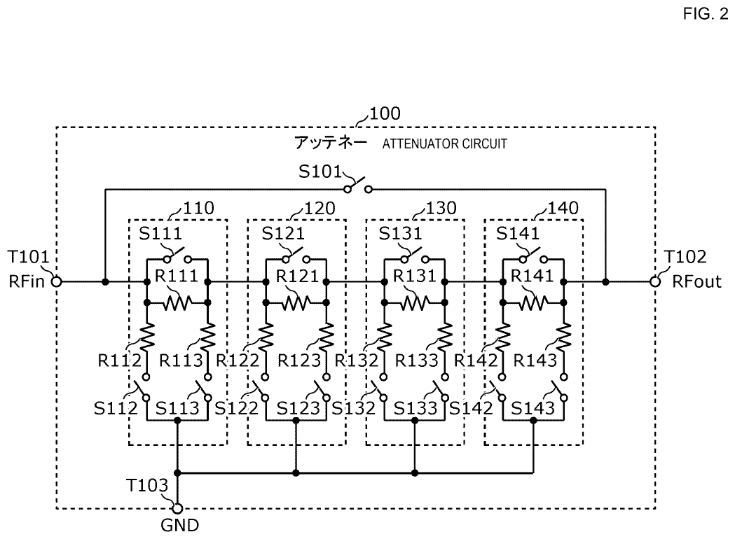

Here, the circuit configuration of the attenuator circuit 100 will be described with reference to FIG. 2. FIG. 2 is a circuit configuration diagram of the attenuator circuit 100 according to the present embodiment.

Note that FIG. 2 illustrates an exemplary circuit configuration, and the attenuator circuit 100 may be implemented using any of various circuit implementations and circuit technologies. Accordingly, the following description of the attenuator circuit 100 is not to be construed as limiting.

The attenuator circuit 100 includes an input terminal T101, an output terminal T102, a ground terminal T103, attenuators 110, 120, 130, and 140, and a switch S101.

The input terminal T101 is an external connection terminal of the attenuator circuit 100 and is a terminal for receiving an RF signal (RFin). The input terminal T101 is connected, outside the attenuator circuit 100, to the switch circuit 27 with the inductor 28 interposed therebetween, and is connected, inside the attenuator circuit 100, to the input end of the attenuator 110.

The output terminal T102 is an external connection terminal of the attenuator circuit 100 and is a terminal for outputting an RF signal (RFout). The output terminal T102 is connected, outside the attenuator circuit 100, to the feedback terminal 50 with the inductor 29 interposed therebetween, and is connected, inside the attenuator circuit 100, to the output terminal of the attenuator 140.

The ground terminal T103 is an external connection terminal of the attenuator circuit 100 and is a terminal for ground connection (GND). The ground terminal T103 is connected to the ground outside the attenuator circuit 100, and, inside the attenuator circuit 100 it is connected to the ground ends of the attenuators 110 to 140.

The switch S101 is an example of a fourth switch and is connected between the input terminal T101 and the output terminal T102 without the attenuators 110 to 140 interposed therebetween. That is, the switch S101 is a switch capable of switching between enabling and disabling conduction of the bypass path of the attenuators 110 to 140, i.e., the switch 101 serves as a bypass switch. Note that the attenuator circuit 100 need not necessarily include the bypass path of the attenuators 110 to 140 and the switch S101.

### 3.1. Circuit Configuration of Attenuator 110

The attenuator 110 is an example of a first attenuator and has the largest attenuation (e.g., 12 dB) among the attenuators 110 to 140. The attenuator 110 includes resistors R111, R112, and R113, and switches S111, S112, and S113.

The resistor R111 is an example of a first resistor and is connected between the input terminal T101 and the output terminal T102. Specifically, one of two ends of the resistor R111 is connected to the input terminal T101, and the other end of the resistor R111 is connected to the output terminal T102 with the attenuators 120 to 140 interposed therebetween. Note that the resistor R111 need not necessarily be included in the attenuator 110.

The resistor R112 is an example of a second resistor and is connected between a path connecting the input terminal T101 and the resistor R111 and ground. Specifically, one of two ends of the resistor R112 is connected to a path connecting the input terminal T101 and the resistor R111, and the other end of the resistor R112 is switchably connected to the ground terminal T103 with the switch S112 interposed therebetween. Note that, when the resistor R113 is included in the attenuator 110, the resistor R112 need not necessarily be included in the attenuator 110.

The resistor R113 is an example of a third resistor and is connected between a path connecting the resistor R111 and the output terminal T102 and ground. Specifically, one of two ends of the resistor R113 is connected to a path connecting the resistor R111 and the attenuator 120, and the other end of the resistor R113 is switchably connected to the ground terminal T103 with the switch S113 interposed therebetween. Note that, when the resistor R112 is included in the attenuator 110, the resistor R113 need not necessarily be included in the attenuator 110.

The switch S111 is an example of a first switch and is connected in parallel with the resistor R111 between the input terminal T101 and the output terminal T102. Specifically, one of two ends of the switch S111 is connected to the input terminal T101 without the resistor R111 interposed therebetween, and the other end of the switch S111 is connected to the output terminal T102 without the resistor R111, but with the attenuators 120 to 140 interposed therebetween. Note that, when the resistor R111 is not included in the attenuator 110, the switch S111 need not necessarily be included in the attenuator 110.

The switch S112 is an example of a second switch and is connected between the resistor R112 and the ground terminal T103. Specifically, one of two ends of the switch S112 is connected to the resistor R112, and the other end of the switch S112 is connected to the ground terminal T103. Note that, when the resistor R112 is not included in the attenuator 110, the switch S112 need not necessarily be included in the attenuator 110.

The switch S113 is an example of a third switch and is connected between the resistor R113 and the ground terminal T103. Specifically, one of two ends of the switch S113 is connected to the resistor R113, and the other end of the switch S113 is connected to the ground terminal T103. Note that, when the resistor R113 is not included in the attenuator 110, the switch S113 need not necessarily be included in the attenuator 110.

In the connection configuration as above, the total attenuation of the attenuator circuit 100 is adjusted by controlling the enabling and disabling of the attenuator 110 using the switches S111 to S113. Specifically, with the switch S111 open and the switches S112 and S113 closed, the attenuator 110 is enabled, and the attenuation of the attenuator 110 is reflected in the total attenuation of the attenuator circuit 100. In contrast, with the switch S111 closed and the switches S112 and S113 open, the attenuator 110 is disabled, and the attenuation of the attenuator 110 is not reflected in the total attenuation of the attenuator circuit 100.

### 3.2. Circuit Configuration of Attenuator 120

The attenuator 120 is an example of a second attenuator and has the second largest attenuation (e.g., 6 dB) among the attenuators 110 to 140. The attenuator 120 is connected between the attenuator 110 and the output terminal T102. The attenuator 120 includes resistors R121, R122, and R123, and switches S121, S122, and S123.

The resistor R121 is an example of a first resistor and is connected between the input terminal T101 and the output terminal T102. Specifically, one of two ends of the resistor R121 is connected to the input terminal T101 with the attenuator 110 interposed therebetween, and the other end of the resistor R121 is connected to the output terminal T102 with the attenuators 130 and 140 interposed therebetween. Note that the resistor R121 need not necessarily be included in the attenuator 120.

The resistor R122 is an example of a second resistor and is connected between a path connecting the input terminal T101 and the resistor R121 and ground. Specifically, one of two ends of the resistor R122 is connected to a path connecting the attenuator 110 and the resistor R121, and the other end of the resistor R122 is switchably connected to the ground terminal T103 with the switch S122 interposed therebetween. Note that, when the resistor R123 is included in the attenuator 120, the resistor R122 need not necessarily be included in the attenuator 120.

The resistor R123 is an example of a third resistor and is connected between a path connecting the resistor R121 and the output terminal T102 and ground. Specifically, one of two ends of the resistor R123 is connected to a path connecting the resistor R121 and the attenuator 130, and the other end of the resistor R123 is switchably connected to the ground terminal T103 with the switch S123 interposed therebetween. Note that, when the resistor R122 is included in the attenuator 120, the resistor R123 need not necessarily be included in the attenuator 120.

The switch S121 is an example of a first switch and is connected in parallel with the resistor R121 between the input terminal T101 and the output terminal T102. Specifically, one of two ends of the switch S121 is connected to the input terminal T101 without the resistor R121, but with the attenuator 110 interposed therebetween, and the other end of the switch S121 is connected to the output terminal T102 without the resistor R121, but with the attenuators 130 and 140 interposed therebetween. Note that, when the resistor R121 is not included in the attenuator 120, the switch S121 need not necessarily be included in the attenuator 120.

The switch S122 is an example of a second switch and is connected between the resistor R122 and the ground terminal T103. Specifically, one of two ends of the switch S122 is connected to the resistor R122, and the other end of the switch S122 is connected to the ground terminal T103. Note that, when the resistor R122 is not included in the attenuator 120, the switch S122 need not necessarily be included in the attenuator 120.

The switch S123 is an example of a third switch and is connected between the resistor R123 and the ground terminal T103. Specifically, one of two ends of the switch S123 is connected to the resistor R123, and the other end of the switch S123 is connected to the ground terminal T103. Note that, when the resistor R123 is not included in the attenuator 120, the switch S123 need not necessarily be included in the attenuator 120.

In the connection configuration as above, the total attenuation of the attenuator circuit 100 is adjusted by controlling the enabling and disabling of the attenuator 120 using the switches S121 to S123. Specifically, with the switch S121 open and the switches S122 and S123 closed, the attenuator 120 is enabled, and the attenuation of the attenuator 120 is reflected in the total attenuation of the attenuator circuit 100. In contrast, with the switch S121 closed and the switches S122 and S123 open, the attenuator 120 is disabled, and the attenuation of the attenuator 120 is not reflected in the total attenuation of the attenuator circuit 100.

### 3.3. Circuit Configuration of Attenuator 130

The attenuator 130 is an example of a third attenuator and has the third largest attenuation (e.g., 3 dB) among the attenuators 110 to 140. The attenuator 130 is connected between the attenuator 120 and the output terminal T102. The attenuator 130 includes resistors R131, R132, and R133, and switches S131, S132, and S133.

The resistor R131 is an example of a first resistor and is connected between the input terminal T101 and the output terminal T102. Specifically, one of two ends of the resistor R131 is connected to the input terminal T101 with the attenuators 110 and 120 interposed therebetween, and the other end of the resistor R131 is connected to the output terminal T102 with the attenuator 140 interposed therebetween. Note that the resistor R131 need not necessarily be included in the attenuator 130.

The resistor R132 is an example of a second resistor and is connected between a path connecting the input terminal T101 and the resistor R131 and ground. Specifically, one of two ends of the resistor R132 is connected to a path connecting the attenuator 120 and the resistor R131, and the other end of the resistor R132 is switchably connected to the ground terminal T103 with the switch S132 interposed therebetween. Note that, when the resistor R133 is included in the attenuator 130, the resistor R132 need not necessarily be included in the attenuator 130.

The resistor R133 is an example of a third resistor and is connected between a path connecting the resistor R131 and the output terminal T102 and ground. Specifically, one of two ends of the resistor R133 is connected to a path connecting the resistor R131 and the attenuator 140, and the other end of the resistor R133 is switchably connected to the ground terminal T103 with the switch S133 interposed therebetween. Note that, when the resistor R132 is included in the attenuator 130, the resistor R133 need not necessarily be included in the attenuator 130.

The switch S131 is an example of a first switch and is connected in parallel with the resistor R131 between the input terminal T101 and the output terminal T102. Specifically, one of two ends of the switch S131 is connected to the input terminal T101 without the resistor R131, but with the attenuators 110 and 120 interposed therebetween, and the other end of the switch S131 is connected to the output terminal T102 without the resistor R131, but with the attenuator 140 interposed therebetween. Note that, when the resistor R131 is not included in the attenuator 130, the switch S131 need not necessarily be included in the attenuator 130.

The switch S132 is an example of a second switch and is connected between the resistor R132 and the ground terminal T103. Specifically, one of two ends of the switch S132 is connected to the resistor R132, and the other end of the switch S132 is connected to the ground terminal T103. Note that, when the resistor R132 is not included in the attenuator 130, the switch S132 need not necessarily be included in the attenuator 130.

The switch S133 is an example of a third switch and is connected between the resistor R133 and the ground terminal T103. Specifically, one of two ends of the switch S133 is connected to the resistor R133, and the other end of the switch S133 is connected to the ground terminal T103. Note that, when the resistor R133 is not included in the attenuator 130, the switch S133 need not necessarily be included in the attenuator 130.

In the connection configuration as above, the total attenuation of the attenuator circuit 100 is adjusted by controlling the enabling and disabling of the attenuator 130 using the switches S131 to S133. Specifically, with the switch S131 open and the switches S132 and S133 closed, the attenuator 130 is enabled, and the attenuation of the attenuator 130 is reflected in the total attenuation of the attenuator circuit 100. In contrast, with the switch S131 closed and the switches S132 and S133 open, the attenuator 130 is disabled, and the attenuation of the attenuator 130 is not reflected in the total attenuation of the attenuator circuit 100.

### 3.4. Circuit Configuration of Attenuator 140

The attenuator 140 is an example of a fourth attenuator and has an attenuation (e.g., 1.5 dB) smaller than that of the attenuator 130. The attenuator 140 is connected between the attenuator 130 and the output terminal T102. Note that the attenuator 140 need not necessarily be included in the attenuator circuit 100. The attenuator 140 includes resistors R141, R142, and R143, and switches S141, S142, and S143.

The resistor R141 is an example of a first resistor and is connected between the input terminal T101 and the output terminal T102. Specifically, one of two ends of the resistor R141 is connected to the input terminal T101 with the attenuators 110 to 130 interposed therebetween, and the other end of the resistor R141 is connected to the output terminal T102. Note that the resistor R141 need not necessarily be included in the attenuator 140.

The resistor R142 is an example of a second resistor and is connected between a path connecting the input terminal T101 and the resistor R141 and ground. Specifically, one of two ends of the resistor R142 is connected to a path connecting the attenuator 130 and the resistor R141, and the other end of the resistor R142 is switchably connected to the ground terminal T103 with the switch S142 interposed therebetween. Note that, when the resistor R143 is included in the attenuator 140, the resistor R142 need not necessarily be included in the attenuator 140.

The resistor R143 is an example of a third resistor and is connected between a path connecting the resistor R141 and the output terminal T102 and ground. Specifically, one of two ends of the resistor R143 is connected to a path connecting the resistor R141 and the output terminal T102, and the other end of the resistor R143 is switchably connected to the ground terminal T103 with the switch S143 interposed therebetween. Note that, when the resistor R142 is included in the attenuator 140, the resistor R143 need not necessarily be included in the attenuator 140.

The switch S141 is an example of a first switch and is connected in parallel with the resistor R141 between the input terminal T101 and the output terminal T102. Specifically, one of two ends of the switch S141 is connected to the input terminal T101 without the resistor R141, but with the attenuators 110 to 130 interposed therebetween, and the other end of the switch S141 is connected to the output terminal T102 without the resistor R141 interposed therebetween. Note that, when the resistor R141 is not included in the attenuator 140, the switch S141 need not necessarily be included in the attenuator 140.

The switch S142 is an example of a second switch and is connected between the resistor R142 and the ground terminal T103. Specifically, one of two ends of the switch S142 is connected to the resistor R142, and the other end of the switch S142 is connected to the ground terminal T103. Note that, when the resistor R142 is not included in the attenuator 140, the switch S142 need not necessarily be included in the attenuator 140.

The switch S143 is an example of a third switch and is connected between the resistor R143 and the ground terminal T103. Specifically, one of two ends of the switch S143 is connected to the resistor R143, and the other end of the switch S143 is connected to the ground terminal T103. Note that, when the resistor R143 is not included in the attenuator 140, the switch S143 need not necessarily be included in the attenuator 140.

In the connection configuration as above, the total attenuation of the attenuator circuit 100 is adjusted by controlling the enabling and disabling of the attenuator 140 using the switches S141 to S143. Specifically, with the switch S141 open and the switches S142 and S143 closed, the attenuator 140 is enabled, and the attenuation of the attenuator 140 is reflected in the total attenuation of the attenuator circuit 100. In contrast, with the switch S141 closed and the switches S142 and S143 open, the attenuator 140 is disabled, and the attenuation of the attenuator 140 is not reflected in the total attenuation of the attenuator circuit 100.

By switching between enabling and disabling each of the attenuators 110 to 140, which have mutually different attenuations, the total attenuation of the attenuator circuit 100 is adjusted.

### 4. Implementation Example of Attenuator Circuit 100

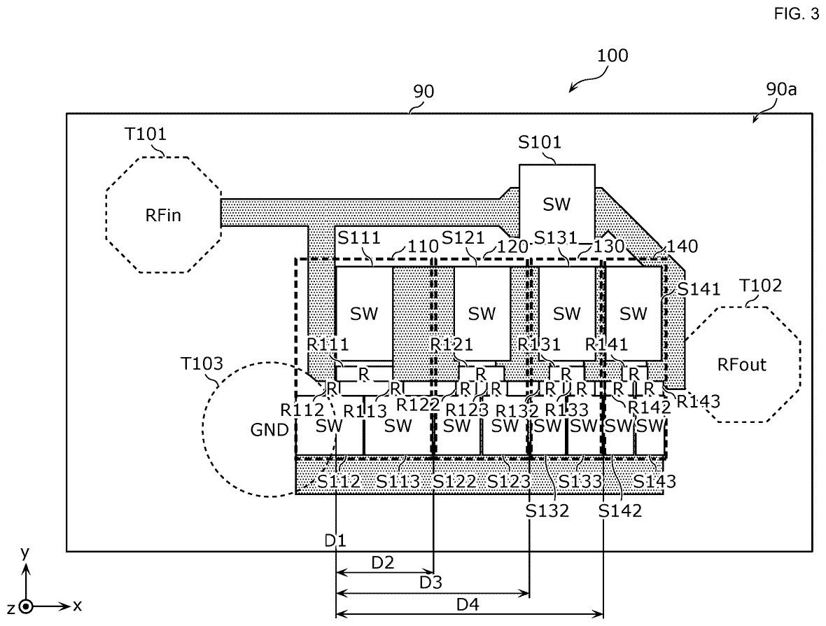

Next, an implementation example of the attenuator circuit 100 with the above-described circuit configuration will be described with reference to FIG. 3. FIG. 3 is a layout diagram of the attenuator circuit 100 according to the present embodiment. In the layout illustrated in FIG. 3, the parasitic ground inductance associated with each attenuator is a function of the length of the conductive path between the shunt resistors of the attenuator and the ground terminal 103. Specifically, the first parasitic ground inductance L1 of the first attenuator 110 is determined by the first distance D1. By configuring the layout such that D1<D2<D3<D4, the circuit creates a graduated inductance profile where the attenuator with the highest sensitivity to ground impedance (the first attenuator 110) is coupled to the ground terminal 103 via the shortest physical path, thereby minimizing its total parasitic inductance relative to the other attenuators in the series.

In FIG. 3, labels representing the respective components are provided so that their positional relationship is easily understandable. Note that these labels need not necessarily be attached to the actual components.

Note that FIG. 3 illustrates an exemplary layout of the attenuator circuit 100, and the attenuator circuit 100 may be implemented using any of various circuit implementations and circuit technologies. Accordingly, the following description of the attenuator circuit 100 is not to be construed as limiting.

The attenuator circuit 100 is implemented as a semiconductor integrated circuit including a substrate 90. The substrate 90 is a semiconductor substrate made of a semiconductor material and may also be referred to as a die or chip. Examples of the semiconductor material for the substrate 90 include monocrystalline silicon, gallium nitride (GaN), and silicon carbide (SiC), but are not limited thereto.

The attenuator 110 is disposed on a main surface 90a of the substrate 90 and/or within the substrate 90. The physical area of the attenuator 110 is defined by the smallest rectangular area surrounding all areas in which the switches S111, S112, and S113 and the resistors R111, R112, and R113 are disposed. The attenuator 110 is disposed between the input terminal T101 and the attenuator 120 when the substrate 90 is viewed in plan.

The attenuator 120 is disposed on the main surface 90a of the substrate 90 and/or within the substrate 90. The physical area of the attenuator 120 is defined by the smallest rectangular area surrounding all areas in which the switches S121, S122, and S123 and the resistors R121, R122, and R123 are disposed. The attenuator 120 is disposed between the attenuators 110 and 130 when the substrate 90 is viewed in plan.

The attenuator 130 is disposed on the main surface 90a of the substrate 90 and/or within the substrate 90. The physical area of the attenuator 130 is defined by the smallest rectangular area surrounding all areas in which the switches S131, S132, and S133 and the resistors R131, R132, and R133 are disposed. The attenuator 130 is disposed between the attenuators 120 and 140 when the substrate 90 is viewed in plan.

The attenuator 140 is disposed on the main surface 90a of the substrate 90 and/or within the substrate 90. The physical area of the attenuator 140 is defined by the smallest rectangular area surrounding all areas in which the switches S141, S142, and S143 and the resistors R141, R142, and R143 are disposed. The attenuator 140 is disposed between the attenuator 130 and the output terminal T102 when the substrate 90 is viewed in plan.

The input terminal T101 (RFin) is a metal electrode (e.g., a copper or aluminum electrode) disposed on the main surface 90a of the substrate 90. The input terminal T101 is connected to the switches S101 and S111 and the resistors R111 and R112 with via conductors penetrating through an insulating film of silicon oxide (SiO₂) or the like, disposed on the main surface 90a of the substrate 90, and wiring on the main surface 90a of the substrate 90 interposed therebetween. Note that, when a circuit element (e.g., the inductor 28) directly connected to the attenuator circuit 100 is included in the same semiconductor integrated circuit as the attenuator circuit 100, the wiring connecting the circuit element and the attenuator circuit 100 is regarded as the input terminal T101.

The output terminal T102 (RFout) is a metal electrode (e.g., a copper or aluminum electrode) disposed on the main surface 90a of the substrate 90. The output terminal T102 is connected to the switches S101 and S141 and the resistors R141 and R143 with via conductors penetrating through an insulating film of silicon oxide (SiO₂) or the like, disposed on the main surface 90a of the substrate 90, and wiring on the main surface 90a of the substrate 90 interposed therebetween.

The ground terminal T103 (GND) is a metal electrode (e.g., a copper or aluminum electrode) disposed on the main surface 90a of the substrate 90. The ground terminal T103 is connected to the switches S112, S113, S122, S123, S132, S133, S142, and S143 with via conductors penetrating through an insulating film of silicon oxide (SiO₂) or the like, disposed on the main surface 90a of the substrate 90, and wiring on the main surface 90a of the substrate 90 interposed therebetween. The ground terminal T103 is disposed between the input terminal T101 and the attenuator 110 when the substrate 90 is viewed in plan. Furthermore, the ground terminal T103 partially overlaps the switch S112 when the substrate 90 is viewed in plan. Note that, in FIG. 3, the ground terminal T103 partially overlaps the attenuator 110 with an insulating film of silicon oxide (SiO₂) or the like, disposed to protect the switch S112 and the like, interposed therebetween, and the ground terminal T103 is not disposed to be in direct contact with the switch S112 and the like. Additionally, bump electrodes made of copper or gold are formed on the input terminal T101, the output terminal T102, and the ground terminal T103.

When the substrate 90 is viewed in plan, a distance D1 (first distance) between the attenuator 110 and the ground terminal T103 (D1=0 in FIG. 3), a distance D2 (second distance) between the attenuator 120 and the ground terminal T103, a distance D3 (third distance) between the attenuator 130 and the ground terminal T103, and a distance D4 (fourth distance) between the attenuator 140 and the ground terminal T103 satisfy the relationship D1<D2<D3<D4. That is, the attenuator 130 is disposed closer to the ground terminal T103 than the attenuator 140, the attenuator 120 is disposed closer to the ground terminal T103 than the attenuator 130, and the attenuator 110 is disposed closer to the ground terminal T103 than the attenuator 120.

### 5. Frequency Characteristics of Attenuator Circuit 100

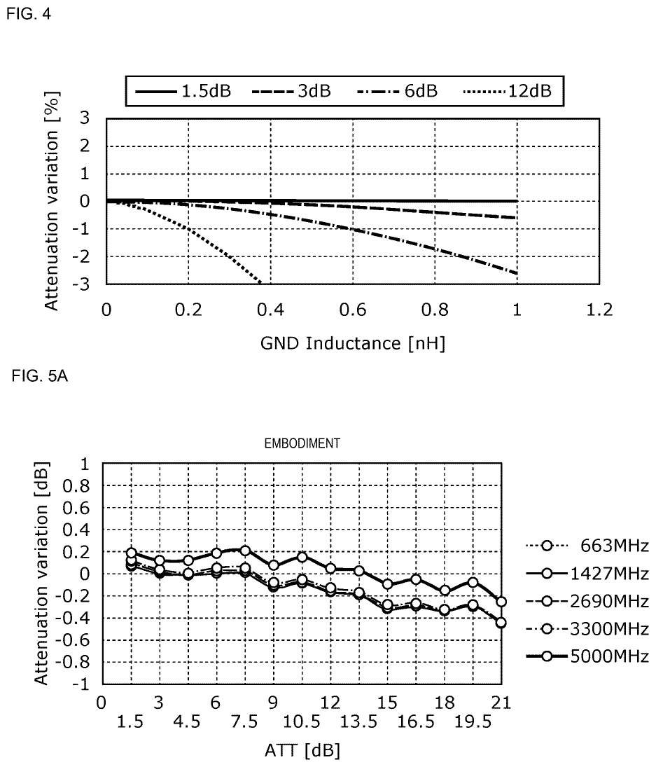

The frequency characteristics of the attenuator circuit 100 configured as above will be described with reference to the drawings. First, the influence of the parasitic inductance (GND inductance) between each of the attenuators 110 to 140 and the ground terminal T103 on the attenuation characteristics will be described with reference to FIG. 4.

FIG. 4 is a graph illustrating the relationship between the attenuation of each of the attenuators 110 to 140 included in the attenuator circuit 100 according to the present embodiment and the GND inductance. In FIG. 4, the vertical axis represents the attenuation variation rate, and the horizontal axis represents the GND inductance. Here, the attenuators 110, 120, 130, and 140 are designed such that, when the GND inductance is zero, their attenuations become 12 dB, 6 dB, 3 dB, and 1.5 dB, respectively.

For all of the attenuators 110 to 140, the attenuation decreases as the GND inductance increases. However, the greater the attenuation of the attenuator is, the larger the percentage decrease in the attenuation becomes in response to an increase in inductance. In other words, even when the GND inductance is the same for all of the attenuators 110 to 140, the rate at which the attenuation decreases differs among the attenuators 110 to 140.

As mentioned above, the attenuation variation due to the GND inductance depends on the attenuation of the attenuator. Note that the attenuation variation due to the GND inductance also depends on frequency. Specifically, the higher the frequency, the greater the rate at which the attenuation of the attenuator decreases in response to an increase in GND inductance. That is, the influence of the GND inductance on the attenuation is greater for attenuators having larger attenuations, and also greater at higher frequencies.

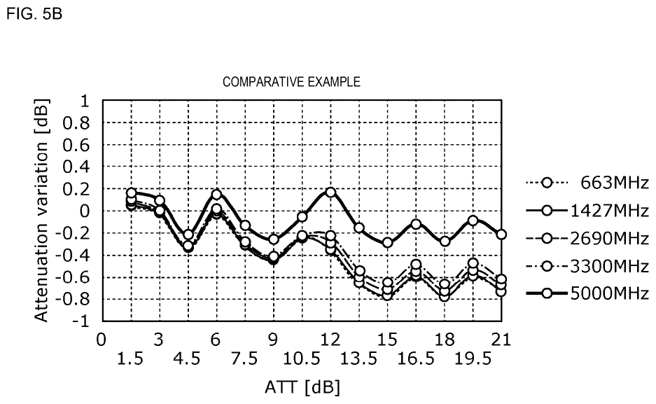

Accordingly, in the present embodiment, the ground terminal T103 is disposed such that the GND inductance decreases as the attenuation of the attenuators 110 to 140 increases, thereby reducing the dispersion of the attenuation variation of the attenuators 110 to 140 due to the GND inductance. That is, the ground terminal T103 is disposed such that D1<D2<D3<D4 is satisfied. Accordingly, the frequency characteristics of the attenuator circuit 100 according to the present embodiment are improved, as illustrated in FIGS. 5A and 5B.

FIG. 5A is a graph illustrating the frequency characteristics of the attenuator circuit 100 according to the present embodiment. FIG. 5B is a graph illustrating the frequency characteristics of an attenuator circuit according to a comparative example. In FIGS. 5A and 5B, the vertical axis represents the attenuation variation, and the horizontal axis represents the target value of the total attenuation of the attenuator circuit. For example, when the target value of the total attenuation of the attenuator circuit is 21 dB, the attenuators 110, 120, and 130 are enabled, and the attenuator 140 is disabled.

Note that, in the comparative example, the ground terminal T103 is disposed between the attenuators 110 and 120, which differs from the present embodiment, while the other configurations are the same as those of the present embodiment.

In the comparative example illustrated in FIG. 5B, the difference between the actual total attenuation and the target value of the total attenuation falls within the allowable range (−0.5 dB to 0.2 dB) at 5000 MHz; however, the difference between the actual total attenuation and the target value of the total attenuation does not fall within the allowable range at frequencies from 663 MHz to 3300 MHz. As demonstrated in FIG. 4, the sensitivity of the attenuation characteristic to parasitic ground inductance is non-linear with respect to the nominal attenuation value. For instance, a parasitic inductance of 0.1 nH causes a significantly greater deviation in the 12 dB attenuator than in the 1.5 dB attenuator. The present disclosure provides a technical solution to this physical phenomenon by selectively budgeting the available parasitic inductance of the substrate layout. By intentionally placing the high-attenuation stages in the lowest-inductance regions of the layout (closest to ground terminal 103), the circuit achieves a flat frequency response across a range of 663 MHz to 5000 MHz that not realized in conventional sequential layouts.

In contrast, in the present embodiment illustrated in FIG. 5A, the difference between the actual attenuation and the target value of the total attenuation falls within the allowable range over the entire frequency range (663 MHz to 5000 MHz).

As described above, by disposing the ground terminal T103 such that the GND inductance decreases as the attenuation of each of the attenuators 110 to 140 with different attenuations increases, it is possible to improve the frequency characteristics of the attenuator circuit 100.

### 6. Conclusion

As described above, the attenuator circuit 100 according to the present embodiment includes: the substrate 90; the input terminal T101, the output terminal T102, and the ground terminal T103 disposed on the substrate 90; and multiple attenuators disposed on the substrate 90 and connected in series between the input terminal T101 and the output terminal T102. Each of the multiple attenuators includes at least one resistor connected between a path connecting the input terminal T101 and the output terminal T102 and the ground terminal T103. The multiple attenuators include: the attenuator 110 having the largest attenuation among the multiple attenuators; the attenuator 120 having the second largest attenuation among the multiple attenuators, and connected between the attenuator 110 and the output terminal T102; and the attenuator 130 having the third largest attenuation among the multiple attenuators, and connected between the attenuator 120 and the output terminal T102. The attenuator 110 is disposed between the input terminal T101 and the attenuator 120 when the substrate 90 is viewed in plan. The attenuator 120 is disposed between the attenuators 110 and 130 when the substrate 90 is viewed in plan. The attenuator 130 is disposed between the attenuator 120 and the output terminal T102 when the substrate 90 is viewed in plan. The ground terminal T103 is disposed between the input terminal T101 and the attenuator 110 when the substrate 90 is viewed in plan.

In another aspect, the attenuator circuit 100 according to the present embodiment includes: the substrate 90; the input terminal T101, the output terminal T102, and the ground terminal T103 disposed on the substrate 90; and multiple attenuators disposed on the substrate 90 and connected in series between the input terminal T101 and the output terminal T102. Each of the multiple attenuators includes at least one resistor connected between a path connecting the input terminal T101 and the output terminal T102 and the ground terminal T103. The multiple attenuators include: the attenuator 110 having the largest attenuation among the multiple attenuators; the attenuator 120 having the second largest attenuation among the multiple attenuators, and connected between the attenuator 110 and the output terminal T102; and the attenuator 130 having the third largest attenuation among the multiple attenuators, and connected between the attenuator 120 and the output terminal T102. When the substrate 90 is viewed in plan, the distance D1 between the attenuator 110 and the ground terminal T103 is shorter than the distance D2 between the attenuator 120 and the ground terminal T103, and the distance D2 is shorter than the distance D3 between the attenuator 130 and the ground terminal T103.

According to these, he attenuator 110 having the largest attenuation is disposed closer to the ground terminal T103 than the attenuator 120 having the second largest attenuation, and the attenuator 120 having the second largest attenuation is disposed closer to the ground terminal T103 than the attenuator 130 having the third largest attenuation. Accordingly, it is possible to dispose the ground terminal T103 such that the GND inductance decreases as the attenuation of the attenuator increases, thereby improving the frequency characteristics of the attenuator circuit 100.

Additionally, for example, in the attenuator circuit 100 according to the present embodiment, each of the multiple attenuators (e.g., 110, 120, and 130) may further include a first resistor (e.g., R111, R121, and R131) connected between the input terminal T101 and the output terminal T102. The at least one resistor may include a second resistor (e.g., R112, R122, and R132) connected between a path connecting the input terminal T101 and the first resistor and the ground terminal T103, and a third resistor (e.g., R113, R123, and R133) connected between a path connecting the first resistor and the output terminal T102 and the ground terminal T103. Each of the multiple attenuators may further include a first switch (e.g., S111, S121, and S131) connected in parallel with the first resistor between the input terminal T101 and the output terminal T102, a second switch (e.g., S112, S122, and S132) connected between the second resistor and the ground terminal T103, and a third switch (e.g., S113, S123, and S133) connected between the third resistor and the ground terminal T103.

According to this, it is possible to improve the frequency characteristics of the attenuator circuit 100 including multiple π-type attenuators.

Furthermore, for example, the attenuator circuit 100 according to the present embodiment may further include the switch S101 connected between the input terminal T101 and the output terminal T102 without any of the multiple attenuators interposed therebetween.

According to this, when all of the multiple attenuators (e.g., 110, 120, and 130) are disabled, it is possible to electrically couple the input terminal T101 and the output terminal T102 without multiple switches (e.g., S111, S112, and S113) included in the multiple attenuators, but with the switch S101 interposed therebetween. That is, when none of the multiple attenuators is enabled, it is possible to bypass the multiple attenuators by closing the switch S101, thereby reducing the loss between the input terminal T101 and the output terminal T102.

Moreover, for example, in the attenuator circuit 100 according to the present embodiment, the ground terminal T103 may at least partially overlap at least one of the switches S112 and S113 of the attenuator 110 when the substrate 90 is viewed in plan.

According to this, it is possible to reduce the GND inductance of the attenuator 110 and to further improve the frequency characteristics of the attenuator circuit 100.

Additionally, for example, in the attenuator circuit 100 according to the present embodiment, the multiple attenuators may further include the attenuator 140 having an attenuation smaller than that of the attenuator 130 and connected between the attenuator 130 and the output terminal T102. The attenuator 140 may be disposed between the attenuator 130 and the output terminal T102 when the substrate 90 is viewed in plan, or the distance D3 may be shorter than the distance D4 between the attenuator 140 and the ground terminal T103 when the substrate 90 is viewed in plan.

Thus, the total attenuation of the attenuator circuit 100 may be varied by using a combination of the four attenuators, which have mutually different attenuations. In the attenuator circuit 100 as described above, it is possible to improve the frequency characteristics of the attenuator circuit 100 by disposing the attenuator 130 having a larger attenuation closer to the ground terminal T103 than the attenuator 140 having a smaller attenuation.

### Other Embodiments

Although the attenuator circuit according to the present disclosure has been described above based on the embodiment, the attenuator circuit of the present invention is not limited to the embodiment described above. Other embodiments realized by combining any components of the above-described embodiment, and modified examples obtained by applying various modifications that may be conceived by those skilled in the art without departing from the spirit of the present invention, as well as various devices incorporating the above-described attenuator circuit, are also included in the present invention.

For example, in the circuit configuration of the attenuator circuit 100 according to the above-described embodiment, other circuit elements or wirings may be inserted in the paths connecting the circuit elements and signal paths disclosed in the drawings. For example, the attenuator circuit 100 may include the inductors 28 and/or 29. Additionally, for example, the attenuator circuit 100 may include an attenuator connected and disposed between the input terminal T101 and the attenuator 110 and having an attenuation smaller than that of the attenuator 110. For example, the attenuator circuit 100 may include an attenuator for fine-tuning that is connected and disposed between the input terminal T101 and the attenuator 110 and has an attenuation smaller than that of the attenuator 140.

Note that, although the attenuators 110 to 140 are π-type attenuators in the above-described embodiment, the attenuators 110 to 140 are not limited thereto. For example, some or all of the attenuators 110 to 140 may be T-type attenuators.

The present invention is widely usable in communication devices such as mobile phones, as an attenuator circuit included in an RF module disposed in a front-end section.

What is claimed is:

1. An attenuator circuit comprising:
a substrate;
an input terminal, an output terminal, and a ground terminal disposed on the substrate; and
a plurality of attenuators disposed on the substrate and connected in series between the input terminal and the output terminal,
wherein each of the plurality of attenuators includes at least one resistor connected between a path connecting the input terminal and the output terminal and the ground terminal;
the plurality of attenuators include:
a first attenuator having a largest attenuation among the plurality of attenuators;
a second attenuator having a second largest attenuation among the plurality of attenuators, and connected between the first attenuator and the output terminal; and
a third attenuator having a third largest attenuation among the plurality of attenuators, and connected between the second attenuator and the output terminal;
the first attenuator is disposed between the input terminal and the second attenuator when the substrate is viewed in plan;
the second attenuator is disposed between the first attenuator and the third attenuator when the substrate is viewed in plan;
the third attenuator is disposed between the second attenuator and the output terminal when the substrate is viewed in plan; and
the ground terminal is disposed between the input terminal and the first attenuator when the substrate is viewed in plan.

2. The attenuator circuit according to claim 1, wherein:
each of the plurality of attenuators further includes a first resistor connected between the input terminal and the output terminal;
the at least one resistor includes:
a second resistor connected between a path connecting the input terminal and the first resistor and the ground terminal; and
a third resistor connected between a path connecting the first resistor and the output terminal and the ground terminal; and
each of the plurality of attenuators further includes:
a first switch connected in parallel with the first resistor between the input terminal and the output terminal;
a second switch connected between the second resistor and the ground terminal; and
a third switch connected between the third resistor and the ground terminal.

3. The attenuator circuit according to claim 2, further comprising:
a fourth switch connected between the input terminal and the output terminal without any of the plurality of attenuators interposed therebetween.

4. The attenuator circuit according to claim 2, wherein:
the ground terminal at least partially overlaps at least one of the second switch and the third switch of the first attenuator when the substrate is viewed in plan.

5. The attenuator circuit according to claim 1, wherein:
the plurality of attenuators further include a fourth attenuator having an attenuation smaller than that of the third attenuator and connected between the third attenuator and the output terminal; and
the fourth attenuator is disposed between the third attenuator and the output terminal when the substrate is viewed in plan.

6. The attenuator circuit according to claim 1, further comprising a bypass switch connected between the input terminal and the output terminal in parallel with the plurality of attenuators.

7. The attenuator circuit according to claim 1, wherein the plurality of attenuators are π-type attenuators.

8. The attenuator circuit according to claim 1, wherein the plurality of attenuators are T-type attenuators.

9. A radio frequency (RF) module comprising:
the attenuator circuit of claim 1; and
a feedback circuit connected to the attenuator circuit.

10. The RF module according to claim 9, further comprising a coupler connected to an input of the feedback circuit.

11. The RF module according to claim 9, further comprising a transmission circuit, wherein the coupler is configured to feed back a portion of a transmission signal from the transmission circuit to the feedback circuit.

12. The RF module according to claim 9, further comprising a first matching inductor connected between the feedback circuit and the input terminal of the attenuator circuit.

13. The RF module according to claim 9, further comprising a second matching inductor connected between the output terminal of the attenuator circuit and a feedback terminal of the RF module.

14. An attenuator circuit comprising:
a substrate;
an input terminal, an output terminal, and a ground terminal disposed on the substrate; and
a plurality of attenuators disposed on the substrate and connected in series between the input terminal and the output terminal,
wherein each of the plurality of attenuators includes at least one resistor connected between a path connecting the input terminal and the output terminal and the ground terminal;
the plurality of attenuators include:
a first attenuator having a largest attenuation among the multiple attenuators;
a second attenuator having a second largest attenuation among the multiple attenuators, and connected between the first attenuator and the output terminal; and
a third attenuator having a third largest attenuation among the multiple attenuators, and connected between the second attenuator and the output terminal; and
when the substrate is viewed in plan a layout of the plurality of attenuators relative to the ground terminal is configured such that a first distance between the first attenuator and the ground terminal is shorter than a second distance between the second attenuator and the ground terminal, and the second distance is shorter than a third distance between the third attenuator and the ground terminal.

15. The attenuator circuit according to claim 14, wherein:
each of the plurality of attenuators further includes a first resistor connected between the input terminal and the output terminal;
the at least one resistor includes:
a second resistor connected between a path connecting the input terminal and the first resistor and the ground terminal; and
a third resistor connected between a path connecting the first resistor and the output terminal and the ground terminal; and
each of the plurality of attenuators further includes:
a first switch connected in parallel with the first resistor between the input terminal and the output terminal;
a second switch connected between the second resistor and the ground terminal; and
a third switch connected between the third resistor and the ground terminal.

16. The attenuator circuit according to claim 15, further comprising:
a fourth switch connected between the input terminal and the output terminal without any of the plurality of attenuators interposed therebetween.

17. The attenuator circuit according to claim 15, wherein:
the ground terminal at least partially overlaps at least one of the second switch and the third switch of the first attenuator when the substrate is viewed in plan.

18. The attenuator circuit according to claim 14, wherein:
the plurality of attenuators further include a fourth attenuator having an attenuation smaller than that of the third attenuator and connected between the third attenuator and the output terminal; and
the third distance is shorter than a fourth distance between the fourth attenuator and the ground terminal when the substrate is viewed in plan.

19. The attenuator circuit according to claim 14, wherein the first distance is substantially zero such that the ground terminal at least partially overlaps a portion of the first attenuator.

20. An attenuator circuit comprising:
a substrate;
an input terminal, an output terminal, and a ground terminal disposed on the substrate; and
a plurality of attenuators connected in series between the input terminal and the output terminal, the plurality of attenuators including a first attenuator having a first attenuation and a second attenuator having a second attenuation smaller than the first attenuation;
wherein, in a plan view of the substrate, the ground terminal is positioned relative to the first and second attenuators such that a first parasitic inductance between the first attenuator and the ground terminal is lower than a second parasitic inductance between the second attenuator and the ground terminal.
